(19) United States
(12) Patent Application Publication
(10) Pub. No.: US 2021/0263116 A1
(43) Pub. Date: Aug. 26, 2021

(54) DEVICE AND METHOD BASED ON DIAMOND NV CENTERS

(71) Applicant: Yissum Research Development Company of the Hebrew University of Jerusalem Ltd., Jerusalem (IL)

(72) Inventors: Nir Bar-Gil, Tel-Aviv (IL); Idan Meirzadh, Azor (IL); Sigal Arielle Wolf, Jerusalem (IL)

(21) Appl. No.: 17/174,082

(22) Filed: Feb. 11, 2021

Related U.S. Application Data
(60) Provisional application No. 62/976,417, filed on Feb. 14, 2020.

(51) Int. Cl. G01R 33/032; G06N 10/00

(52) U.S. Cl. CPC G01R 33/032; G06N 10/00

(57) ABSTRACT

The invention generally concerns an enhanced process for detecting spin states of nitrogen vacancy centers in diamonds.

The present US application claims benefit of priority from U.S. Provisional Application No. 62/976,417 filed Feb. 14, 2020.

### TECHNOLOGICAL FIELD

The invention is generally about novel devices and methods of reading NV centers spin state in diamonds and uses thereof.

### BACKGROUND

Recently, the world observed great advances in detecting and controlling quantum mechanical states. Various systems have been developed based on that same technology including circuits [1], cold ions [2] and spins in semiconductors [3]. Still, most quantum platforms prevailing today face substantial technical challenges. One of the most prominent challenges is reliability of measuring the quantum state. As known, the issue of precise measurement is one of the earliest and most momentous aspects in the theory of quantum mechanics and is said to be the most essential aspect for many practical applications. Such a problem can be easily applied to the nitrogen-vacancy (NV) center in a diamond which is considered a gold standard in solid-state qubit for a wide range of quantum technologies.

The diamond NV center is a classic defect spin qubit and is the one which is most intensely studied. Such centers act as a subset of point defects and may conveniently function as qubits with optical capability, spin coherence characteristics, and room temperature functionalities. Indeed, being a platform for multipurpose functionalities, NV centers have been utilized for various purposes, such as examination and research of core principles of quantum mechanics, design of quantum memory [4], research of individual nuclear spins [5], research of proteins [6], chemicals and molecules [7], and engineering sensors in the nanoscale level [8].

In the course of years, various techniques have been developed for measuring NV centers spin state such as counting the main photoluminescence (PL) photons (640-800 nm) emitted in the first 300 nano seconds of illumination. The received value is averaged over many cycles; thereby, the NV center's ground state spin projection can be deduced.

Another technique found to be theoretically effective to improve the readout of NV center's optical spin is nanophotonic engineering of the local density of optical states which includes incorporation of quantum emitters within nanophotonic devices to therefore increase the Purcell effect and/or the collection efficiency.

Further techniques include low temperature resonant readout, nuclear assisted readout and spin to charge conversion technique.

In general, most of the readout enhancement techniques seek to increase the number of detected photons, either by modifying the emission rate or by mapping the electron spin state into a longer living observation. Still, although the extensive effort that was put in that domain, all the aforementioned techniques all the same require many repetitions of each measurement, cold temperatures or long measurements.

With that being said, a fast, high fidelity and accuracy spin state readout is still absent.

### REFERENCES

[1] Gambetta, J. M.; Chow, J. M.; Steffen, M. Building logical qubits in a superconducting quantum computing system. NPJ Quantum Inf. 2017, 3, 2.
[2] Brown, K. R.; Kim, J; Monroe, C. Co-designing a scalable quantum computer with trapped atomic ions. NPJ Quantum Inf. 2016, 2, 16034.
[3] Awschalom, D. D.; Bassett, L. C.; Dzurak, A. S.; Hu, E. L.; Petta, J. R. Quantum Spintronics: Engineering and Manipulating Atom-Like Spins in Semiconductors. Science 2013, 339, 1174-1179.
[4] Dutt, M. V. G.; Childress, L.; Jiang, L.; Togan, E.; Maze, J.; Jelezko, F.; Zibrov, A. S.; Hemmer, P. R.; Lukin, M. D. Quantum Register Based on Individual Electronic and Nuclear Spin Qubits in Diamond. Science 2007, 316, 1312-1316.
[5] Childress, L.; Gurudev Dutt, M. V.; Taylor, J. M.; Zibrov, A. S.; Jelezko, F.; Wrachtrup, J.; Hemmer, P. R.; Lukin, M. D. Coherent Dynamics of Coupled Electron and Nuclear Spin Qubits in Diamond. Science 2006, 314, 281 285.
[6] Lovchinsky, I.; Sushkov, A. O.; Urbach, E.; de Leon, N. P.; Choi, S.; De Greve, K.; Evans, R.; Gertner, R.; Bersin, E.; Müller, C.; et al. Nuclear magnetic resonance detection and spectroscopy of single proteins using quantum logic. Science 2016, 351, 836-841.
[7] Aslam, N.; Pfender, M.; Neumann, P.; Reuter, R.; Zappe, A.; Fávaro de Oliveira, F.; Denisenko, A.; Sumiya, H.; Onoda, S.; Isoya, J.; et al. Nanoscale nuclear magnetic resonance with chemical resolution. Science 2017, 357, 67-71.
[8] Casola, F.; van der Sar, T.; Yacoby, A. Probing condensed matter physics with magnetometry based on nitrogen-vacancy centers in diamond. Nat. Rev. Mater. 2018, 3, 17088.

### SUMMARY OF THE INVENTION

Nitrogen-Vacancy (NV) centers in diamond have been used in recent years for a wide spectrum of applications, ranging from nano-scale NMR to quantum computation. These applications depend strongly on the ability to effectively read the NV center's spin state.

The inventors of the technology disclosed herein have developed and demonstrated a new process for reading the NV center's spin state, using a weak optical transition in the singlet manifold. In the exemplified process, the number of photons collected from each spin state was calculated and an enhancement of two orders of magnitude in spin readout signal-to-noise ratio was observed, making single-shot spin readout within reach. Thus, the process of the invention provides an improved enhancement in sensitivity for every NV based sensing application, thereby removing a major obstacle from using NVs for quantum computation and sensing purposes.

Thus, according to a first aspect of the disclosure, the invention concerns a process for measuring NV centers spin state in a diamond sample, the process comprising applying an optical excitation radiation (or irradiating) to a diamond having at least one nitrogen vacancy (NV) center, the radiation being/comprising green light, or having a wavelength between 400 and 638 nm (to thereby excite the NV centers in the diamond), and detecting output optical radiation emitted from the at least one NV centers.

The invention further provides a process for enhancing sensitivity in measuring NV centers spin state in a diamond sample, the process comprising applying an optical excitation radiation to a diamond having at least one nitrogen vacancy (NV) center, the radiation being/comprising green light or light having a wavelength between 400 and 638 nm (to thereby excite the NV centers in the diamond), enhancing output optical radiation (fluorescence emission) and detecting, measuring and/or counting photons emitted from the at least one NV centers.

In some embodiments, the enhancing comprises or consists illuminating the sample with light having a wavelength between 700 and 1042 nm.

In some further embodiments, the detecting, measuring and/or counting is of photons having a wavelength ranging between 700 and 1050 nm.

In some embodiments, the detecting, measuring and/or counting is of photons having a wavelength ranging between 1040 and 1050 nm.

Further provided is a process for enhancing sensitivity in measuring NV centers spin state in a diamond sample, the process comprising:
irradiating a diamond having at least one nitrogen vacancy (NV) center with a green light or a light having a wavelength between 400 and 638 nm (to thereby excite the NV centers),
irradiation the diamond with an infrared (IR) light or a light having a wavelength between 700 and 1042 nm, and
detecting photons emitted from the at least one NV centers.

In some embodiments, the detecting of photons comprises or consists detection of photons at the IR spectral regime or photons having a wavelength between 700 and 1050 nm. In some embodiments, the detection is of photons having a wavelength between 1040 and 1050 nm.

In some embodiments, the process further comprises a step of enhancing fluorescence emission signal and collection (by coupling the singlet transition emission to a suitable photonic structure).

Thus, a further process is provided for enhancing sensitivity in measuring NV centers spin state in a diamond sample, the process comprising:
irradiating a diamond having at least one nitrogen vacancy (NV) center with a green light or a light having a wavelength between 400 and 638 nm (to thereby excite the NV centers),
irradiation the diamond with an IR light or a light having a wavelength between 700 and 1042 nm,
enhancing fluorescence emission signal and collection (by coupling the singlet transition emission to a suitable photonic structure), and
detecting photons emitted from the at least one NV centers in the IR spectral regime, or detecting photons having a wavelength between 1040 and 1050 nm.

Also provided is a device comprising a diamond sample comprising at least one NV center, a first illumination source configured and operable to illuminate the diamond sample at a wavelength in the green spectral range, e.g., between 400 and 638 nm, a photon counter, and optionally a second illumination source configured and operable to illuminate the diamond sample at the IR spectral regime, or at a wavelength between 700 and 1042 nm.

Further, a device is provided comprising a diamond having at least one NV center comprising one or more electronic spins, wherein the electronic spins are configured to align with the diamond crystallographic axis in response to optical excitation radiation applied to the at least one NV center; and a photon counter configured to detect output optical radiation correlated with the electronic spins, after the electronic spins have been subject to an optical enhancement, to thereby detect the magnetic field.

In embodiments, the detection of output optical radiation is in the IR spectral range or between 700 and 1050 nm (e.g., IR range). In some specific embodiments, the detection is of photons having a wavelength ranging between 1040 and 1050 nm (e.g., IR range).

In the context of the present invention, the terms “infrared (IR) range”, “infrared (IR) spectral regime” or “infrared (IR)” refer to wavelengths longer than those of a visible light (invisible to the human eye), as known in the art, and specifically to those which range between 700 and 1050 nm. In some aspects or embodiments as demonstrated herein, the range may be between 700 and 1042 nm, or between 1040 and 1050 nm.

The terms “green light”, “green excitation”, “green laser” and “green pulse” refer to any excitation process performed by light having wavelengths ranging between 400 and 638 nm, or a light at wavelengths around 550 nm.

The “diamond sample” is a single or a plurality of diamonds, each having one or more nitrogen vacancy (NV) centers. The diamond may be selected from bulk diamonds, a diamond membrane, a nano-diamond, a micro-diamond and any diamond structure including at least one NV centers. The “NV center” embedded in the diamond is a color center. The NV center comprises a nitrogen atom next to a carbon vacancy.

The nitrogen atom, which may be located within the diamond crystal lattice, is covalently bonded to three carbon atoms. The NV centers can occur naturally within the diamond, or can be created using N⁺ ion implantation or in nitrogen rich diamonds by irradiation which creates vacancies in the diamond and subsequent annealing which causes the vacancies to migrate towards the nitrogen atoms to produce an NV center.

When the NV centers are optically excited by light generated by an illumination source, via a single or multiple photon process, electron excitation occurs from the ground state (³A) of the NV centers to their excited state (³E). The excitation (illumination) can be performed from any angle with respect to the NV centers, e.g., from the top of or above the diamond sample. An additional illumination/excitation process may be used in order to excite the electrons of the NV centers from ¹E to ¹A energy level. This additional step, as disclosed herein may be carried out to increase the number of emitted photons and improve the readout fidelity and single-to-noise ratio (SNR). The additional excitation may be via the same or different illumination source, as described herein.

Following illumination, fluorescence is emitted from the sample (usually due to the decay from the ¹A and ¹E energy levels). The emitted photons (fluorescence) are collected and counted by a photon counter positioned at any angle in relation to the NV centers.

In some embodiments, the process further comprises irradiating the diamond with a second light source for exciting the at least one NV centers at a different wavelength, i.e., at the infrared spectral range, namely exciting electrons in the at least one NV center to shift from a singlet ground state energy level (¹E) to a singlet excited state energy level (¹A), to increase the fluorescence signal and to further strengthen the singlet fluorescence signal.

In some specific embodiments, a delay (τ) is introduced between the first (green) and the second (IR) excitation steps. In other words, in cases where two excitations are performed (using green and infrared light), a short delay is introduced between the first and the second excitation steps to avoid undesired ionization from the excited triplet state (energy level).

In embodiments, the delay extends between 0 ns to 100 ns.

In some cases, a weakening of the spin readout occurs due to the weak fluorescence signal caused by the non-radiative nature of the transition ¹E->¹A and the low detection efficiency of the photon counter, e.g., silicon-based single photon counters in the near IR wavelengths. To enhance the singlet fluorescence signal, the process may comprise a step of enhancing the emitted singlet fluorescent signal. Enhancement is achieved through modifying the coupling between the light field and the singlet transition, which can result in stronger emission and/or more directed emission. Putting it differently, enhancement may be achieved by enhancing the optical coupling between ¹E and ¹A energy levels and/or by increasing emission directionality; or by utilizing optical antennas, plasmonic antennas, hyperbolic metamaterials (HMM) or photonic crystal cavity.

A second illumination source may be used to excite the diamond center with a light of a different wavelength (IR), namely to illuminate the diamond sample to shift electrons from a singlet ground state energy level (¹E) to a singlet excited state energy level (¹A).

In some embodiments, the emitted photons have a wavelength at the IR range.

In some embodiments, the second illumination source operates in a wavelength range of between 700 and 1042 nm (˜1 millimeters).

The first and second illumination sources may be separate or may be comprised within a single illumination device which is configured and operable for illuminating in various wavelengths.

In some embodiments, the diamond sample comprises a synthetic diamond. In some other embodiments, the diamond is a natural diamond.

The photon counter is any device comprising a single-photon detector (SPD). The SPD typically emits a pulse of signal every time a photon is detected, wherein the total number of pulses is counted, giving an integer number of photons detected per measurement period. The photon counter used according to the invention may be selected from a photodiode, a single photon detector, a superconducting nanowire, a photomultiplier, a Geiger counter, a single-photon valance diode, a transition edge sensor, a scintillation counters and a charge-coupled device.

A non-limiting implementation of a device according to the invention is depicted in FIG. 1.

Device 1 comprises a diamond sample 2 comprising a layer comprising at least one NV center 3, a structure 4 for increasing the emitted singlet fluorescence signal (which is an optional structure of the device), illumination source 5 and a photon counter 6. Further presented in the Figure is the excitation process, where NV centers in layer 3 are optically excited by light generated by an illumination source 5, via a single or multiple photon process. The excitation is from the ground state (³A) of the NV centers electrons to their excited state (³E). The excitation (illumination) can be performed from any angle with respect to the NV centers. In the example shown in FIG. 1, illumination is from above the diamond sample (which comprises the NV centers) and is presented by the dashed line.

As noted herein, an additional illumination/excitation process may be performed in order to excite the electrons of the NV centers from ¹E to ¹A energy level. Such a process is carried out to increase the number of emitted photons and improve the readout fidelity and SNR. The additional illumination is introduced to the sample via the same or different illumination source as described above. In the specific example of device 1, the two illumination processes are performed via a single illumination source 5, where the second illumination is shown by the dotted line.

After illumination, fluorescence is emitted from the sample (usually due to the decay between ¹A and ¹E energy levels) as shown by the solid line in the exemplary device 1. The emitted photons (fluorescence) are collected and counted by a photon counter 6. Collection of photons can be performed from any angle in relation to the NV centers.

Devices of the herein invention may also be a part of a larger and more complex system. Such a system may comprise, apart from the diamond sample, the illuminations device(s) and the photon counter(s), a microwave radiation element, a polarization control element, a light modulation device, a lock-in amplifier, a time tagging element, a data acquisition, a processing device, a sequence generation device, a magnetic field generation element, or an optical element such as mirrors, lenses, filters and objectives.

In another appearance of the invention, there is provided a method comprising (a) exciting electrons in at least one NV center of a diamond sample using a light with a wavelength at the green spectral range; (b) exciting electrons in the NV centers using infrared light, with a wavelength at the IR spectral range and (c) measuring emitted fluorescence in the IR spectral range (by counting the number of photons emitted).

In some embodiments, the excitation with the green light is between 1 and 3 us or between 1 and 100 ns. In some embodiments, the excitation with infrared radiation is between 1 ns and 5 ms or between 1 ns and 1 ms.

In other embodiments, in a process of the invention, a (strong) green pulse is applied to first excite the NV, wherein the pulse is typically 1-100 ns long; followed by a (strong) longer IR pulse to continuously excite the NV singlet manifold until it decays, the IR pulse being between 1 ns-1 ms long.

Negatively charged nitrogen-vacancy (NV⁻) centers in a diamond have been previously suggested as a promising magnetic field sensor. This is so since the spin states of the electrons trapped in the NV centers are optically accessible, therefore allowing readout of their energy states. Such availability of spin states and spin transitions allows highly-sensitive sensing of magnetic fields and potentially provides a technology for methods and sensors for a wide range of applications (such as sensing electric field, magnetic field, temperature and even quantum computing).

Specifically, magnetic sensing using the diamond NV centers has been considered as one of the most highly sensitive sensors, which may potentially produce a magnetic detection in the order of a femtotesla when comparing to the sensitivity of other magnetic sensing technologies, such as the superconducting quantum interference device or optically pumped atomic magnetometer. Methods and devices of the invention allow for better readouts of the spin states and thus a better sensing/detection platform for the magnetic field.

The diamond NV centers are relatively insulated from magnetic interference from other spins. The NV centers in the diamond may provide electronic spins that have almost no interaction with the background lattice, i.e., nearly pure electronic spins that are practically frozen in space, with almost no corrupting interactions with the background lattice. These electronic spins may be optically detectable with unique optical signatures that allow them to be used for magnetometry.

Thus, further provided by the invention is a magnetic field detector (or a magnetometer) in a form of a device according to the invention. The device, being a magnetometer, comprises a diamond having at least one NV center comprising one or more electronic spins, wherein the electronic spins are configured to align with a the diamond crystallographic axes in response to optical excitation radiation applied to the at least one NV center; and a photon counter configured to detect output optical radiation correlated with the electronic spins, after the electronic spins have been subject to microwave irradiation and an optical enhancement, to thereby detect the magnetic field.

The magnetic field may be detected or measured by a variety of methodologies, as known in the art. Generally, photons are counted in conjunction with the application of microwave radiation, at varying frequencies. The change in photon count as a function of microwave radiation frequency is translated into a magnetic field measurement, as thus change depends on the magnetic field. Experimental and processing conditions are detailed further in the art, see for example Farchi et al., “Quantitative Vectorial Magnetic Imaging of Multi-Domain Rock Forming Minerals Using Nitrogen-Vacancy Centers in Diamond”, SPIN, Vol. 7, No. 3 (2017) 1740015, incorporated herein by reference.

The microwave irradiation can be supplied in various ways. Generally speaking, the microwave irradiation is approximately in the 2-4 GHz range, with a power on the scale of 1 W. Other values may also be applicable and may vary based on the specific experimental conditions.

As noted herein, the proposed scheme for enhanced spin readout is relevant for additional NV applications. Apart from enhancement in sensitivity for magnetic sensing scenarios, methods and devices of the invention are suitable for additional applications, as follows:

Quantum Communications:

Significant effort is being invested in developing optical communications beyond the current state-of-the-art, to enable the transfer of quantum information. Such capabilities are important for future applications related to quantum computing and quantum memories, as well as for secure communications, resilient to quantum attacks. A basic building block in quantum communications is the single-photon source, which efficiently connects a material system to a photonic bus. In addition, a quantum memory node/quantum repeater requires the efficient coupling of a quantum system to light. Both of these elements can be realized by NV centers in diamond. However, the limited optical coupling of the NV poses a significant challenge in utilizing it for efficient quantum communications.

The proposed scheme for enhanced coupling of the NV to an optical mode addresses this challenge, and enables an NV-based material-photonic bridge, suitable as both a single-photon source and as a quantum memory node.

Spintronic Devices

Future computing architectures focus on ultrafast performance together with low energy consumption. Achieving these goals requires a new paradigm for information storage and processing, which is based on magnetic instead of electronic signals. This approach is referred to as spintronics. Spintronic devices are based on combination of magnetic materials, and while they enable fast and efficient control, their local addressing poses a challenge.

The solid-state platform of NV centers in diamond is beneficial for integrating it into spintronic devices as a hybrid platform, and high-resolution optical access to the NV spin degree of freedom offers a handle for local spin manipulation and readout.

The efficient optical control provided by the proposed scheme can therefore enhance the performance of hybrid diamond-spintronic devices for information processing and storage.

Thus the invention further contemplates devices selected from a magnetic field detector, a quantum communication device, a spintronic device, and others.

In summary, some of the aspects and embodiments disclosed herein include: A process for enhancing sensitivity in measuring spin state in nitrogen vacancy (NV) centers in a diamond sample, the process comprising applying an optical excitation radiation to a diamond having at least one nitrogen vacancy (NV) center, the radiation comprising light having a wavelength between 400 and 638 nm, illuminating the sample with light having a wavelength between 700 and 1042 nm, and detecting, measuring and/or counting photons emitted from the at least one NV center.

Another process is provided for enhancing sensitivity in measuring spin state in nitrogen vacancy (NV) centers in a diamond sample, the process comprising:
irradiating a diamond having at least one nitrogen vacancy (NV) center with a light having a wavelength between 400 and 638 nm, to thereby excite the NV centers,
irradiating the diamond with a light having a wavelength between 700 and 1042 nm, and
detecting photons emitted from the at least one NV centers, at wavelengths ranging between 700 and 1050 nm.

In a process of the invention, the step of detecting photons emitted from the at least one NV centers is at wavelengths between 1040 and 1050 nm.

In a process of the invention, the process further comprises a step of enhancing the fluorescence emission signal.

In a process of the invention, said enhancing fluorescence emission comprises coupling a singlet transition emission to a photonic structure.

In a process of the invention, the photonic structure is an optical antenna, a plasmonic antenna, a hyperbolic metamaterial (HMM) or a photonic crystal cavity.

In a process of the invention, the optical excitation with light in a wavelength between 400 and 638 nm is for a duration between 1 and 3 us.

In a process of the invention, the illuminating with light in a wavelength between 700 and 1042 nm is for a duration between 1 ns and 5 ms or between 1 ns and 1 ms.

Also provided is a device comprising a diamond sample comprising at least one nitrogen vacancy (NV) center, a first illumination source configured and operable to illuminate the diamond sample at a wavelength in a spectral range between 400 and 638 nm, a photon counter, and a second illumination source configured and operable to illuminate the diamond sample at a wavelength in a spectral range between 700 and 1042 nm.

A magnetometer device is also provided which comprises a diamond having at least one nitrogen vacancy (NV) center comprising one or more electronic spins, wherein the electronic spins are configured to align with the diamond crystallographic axis in response to optical excitation radiation applied to the at least one NV center; and a photon counter configured to detect output optical radiation at the IR range correlated with the electronic spins when subjected to an optical enhancement.

In a device according to the invention, the photons counter is a device comprising a single-photon detector (SPD).

In a device according to the invention, the photon counter is selected from a photodiode, a single photon detector, a superconducting nanowire, a photomultiplier, a Geiger counter, a single-photon valance diode, a transition edge sensor, a scintillation counters and a charge-coupled device.

In a device according to the invention, the photons counter is a device comprising a single-photon detector (SPD).

In a device according to the invention, the photon counter is selected from a photodiode, a single photon detector, a superconducting nanowire, a photomultiplier, a Geiger counter, a single-photon valance diode, a transition edge sensor, a scintillation counters and a charge-coupled device.

In a device according to the invention, the device further comprises a microwave radiation element, a polarization control element, a light modulation device, a lock-in amplifier, a time tagging element, a data acquisition, a processing device, a sequence generation device, a magnetic field generation element, or an optical element.

A system is also provided which comprises a device according to the invention.

The device of the invention may be a magnetometer or a quantum communication device or a spintronic device.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1 provides an exemplary device for NV centers spin state readout according to some embodiments of the invention.

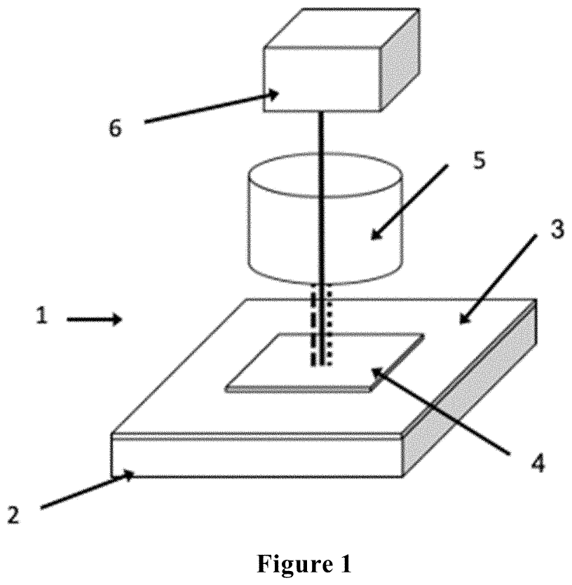

FIG. 2 is an energy-level diagram and relevant transitions for the neutral and negatively charged NV center. Green excitation is depicted with green arrows, red fluorescence is depicted with downward red arrows, IR excitation and fluorescence are depicted with purple and red arrows, respectively, nonradiative decay is depicted with blue arrows, ionization and recombination transitions depicted with dashed black arrows.

FIGS. 3A-D provide graphs of SNR as a function of green excitation power and pulse duration for bulk (FIGS. 3A and 3C) and surface (FIGS. 3B and 3D) NVs, without (FIGS. 3A and 3B) and with (FIGS. 3C and 3D) time normalization.

FIGS. 4A-E are graphs of IR fluorescence spin-state readout. FIG. 4A depicts the pulse sequence for the IR fluorescence spin readout. FIGS. 4B-E shows SNR as a function of IR excitation power and pulse duration for bulk NV (FIGS. 4B and 4D) and surface (FIGS. 4C and 4E) NVs, with (FIGS. 4D and 4E) and without (FIGS. 4B and 4C) normalization.

FIGS. 5A-E provide schematic drawings of one of the suggested experimental setups and electric field energy density of the photonic crystal structure. FIG. 5A is a schematic drawing of one of the suggested experimental setups. FIG. 5B is presents photonic crystal structure and electric field near-field energy density. FIG. 5C presents electric field far-field energy level density, showing highly directed emission from the cavity.

FIGS. 6A-D provide graphs of expected spin state SNR, fidelity and number of photons emitted as a function of Purcell factor under 1 W excitation (inside the cavity), 1 μs readout duration and an optimized delay duration τ=10 ns. FIGS. 6A-B shows spin-state readout SNR (FIG. 6A) and fidelity (FIG. 6B) for bulk (blue lined) and surface (red lines) NVs. The black line illustrates the highest SNR/fidelity possible for bulk NV using red fluorescence. FIGS. 6C-D shows number of photons emitted during the singlet excitation for ms=0 (black lines) and ms=±1 (green lines) for bulk (FIG. 6C) and surface (FIG. 6D) NVs.

FIGS. 7A-D present graphs of the expected spin-readout SNR and fidelity as a function of Purcell factor and laser power. FIGS. 7A-B are graphs of the expected spin state SNR for bulk (FIG. 7A) and surface (FIG. 7B) NV. FIGS. 7C-D are graphs of the expected fidelity for (FIG. 7A) bulk and (FIG. 7B) surface NVs.

### DETAILED DESCRIPTION OF EMBODIMENTS

In the below examples there is provided a novel calculation of the red fluorescence-based spin state readout, a novel method of reading the NV center's spin state, using the weak fluorescence emitted in the singlet manifold, and calculation of the expected signal-to-noise ratio (SNR) by numerically solving the master equation, for both surface and bulk NVs. From these results, there is described a regime of excitation parameters in which a significant increase of the NV's spin state readout SNR is expected. Finally, an example of utilization of a photonic crystal structure to increase the radiative coupling of the singlet transition is described, which shows that a dramatic enhancement of the spin state SNR can be achieved using this or similar structures, towards a single-shot readout.

### Example 1: Calculating the Spin Readout SNR

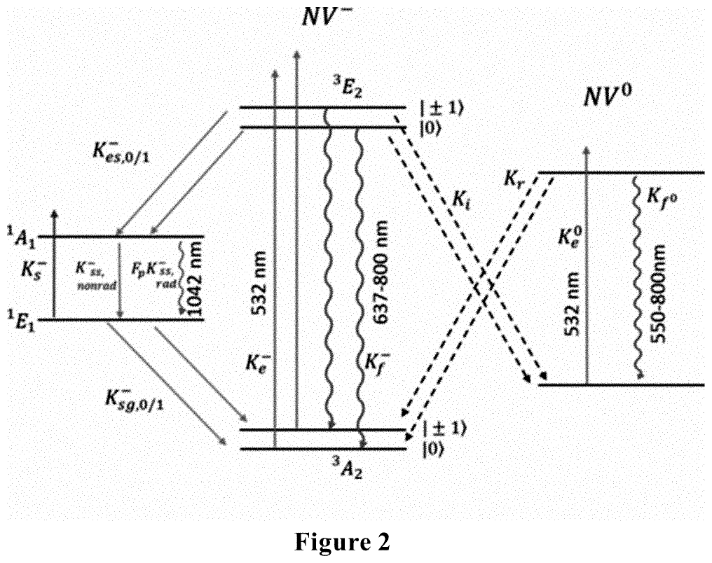

The negatively charged NV center consists of 2 adjacent lattice sites occupied by a nitrogen atom and a vacancy inside a diamond crystal. The electronic ground state of the NV center is a spin triplet with a 2.87 GHz zero-field splitting between spin projections mₛ=0 and mₛ=1. The electronic excited states contain a spin triplet with a strong radiative coupling and a spin singlet with a much weaker radiative coupling. FIG. 2 depicts a simplified energy level diagram of NV⁻ and NV⁰, together with the main transitions. In red fluorescence-based spin state readout scheme, an NV in the triplet ground state (³A) is excited to the triplet excited state (³E) using green light, and the red fluorescence during the decay back to the ground state is collected. The number of photons collected from each of the spin states dictates the SNR, which is defined as:

$$SNR = \frac{\vert {N}_{0} - {N}_{1} \vert}{\sqrt{{N}_{0} + {N}_{1}}} \qquad ( 1 )$$

where N₁ denotes the number of photons collected when the NV is initialized to its mₛ=|i> state, where i can be 0 or 1.

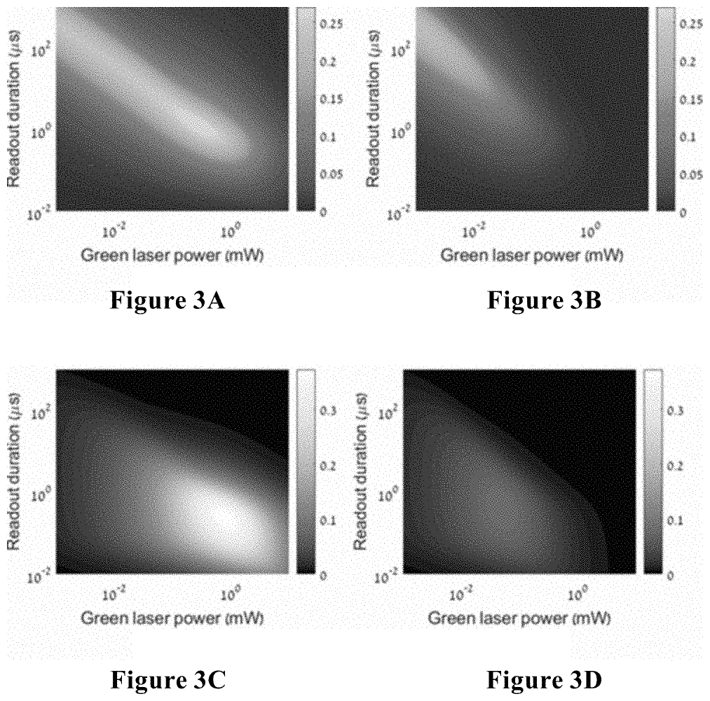

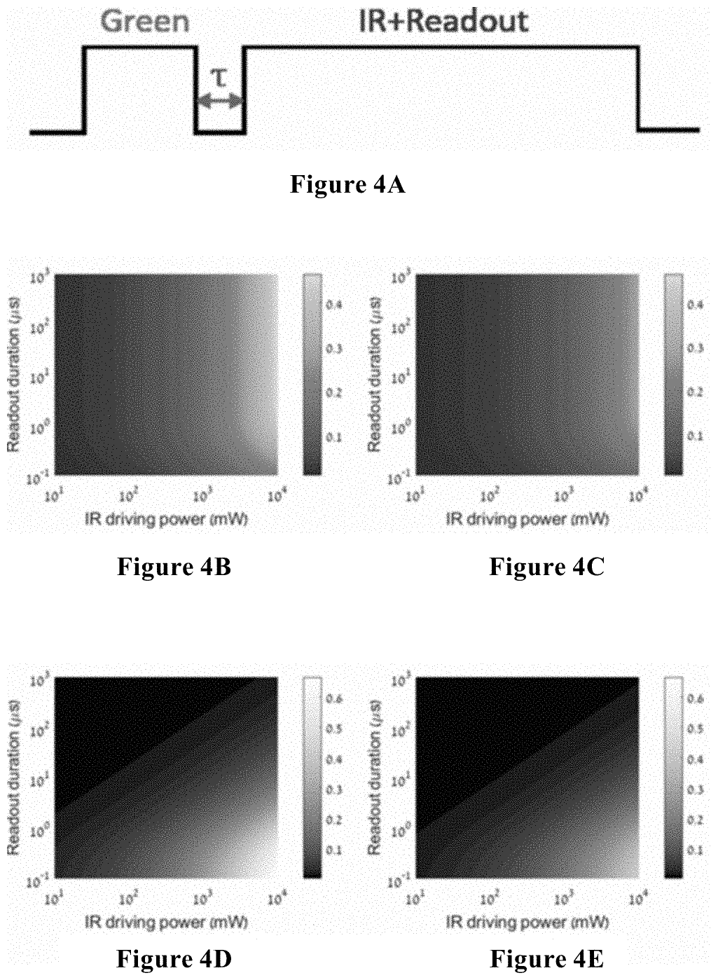

Herein, the spin readout SNR is calculated using green excitation and red fluorescence (but can also be calculated using green excitation alone), as a function of readout duration and excitation power for a confocal system, for both surface and bulk NVs, assuming perfect collection and detection efficiencies. In addition, fluorescence from NV⁰ is ignored, although it overlaps with the NV's. The SNR is calculated numerically, using an eight level model, over a wide range of parameters. The rate equations dictating the populations for FIG. 3, as well as for FIG. 4, are the following:

P_{g,0}⁻=−Kₑ⁻P_{e,0}⁻+Kⱼ⁻P_{e,0}⁻+K_{sg,0}P_{s,g}+½(Kr_{G}+Kr_{IB})Pₑ⁰

P_{g,1}⁻=−Kₑ⁻P_{e,1}⁻+Kⱼ⁻P_{e,1}⁻+K_{sg,1}P_{s,g}+½(Kr_{G}+Kr_{IB})Pₑ⁰

P_{e,0}⁻=−(Kⱼ⁻+K_{es,0}+Ki_{G}+Ki_{IR})P_{e,0}⁻+Kₑ⁻P_{g,0}

P_{e,1}⁻=−(Kⱼ⁻+K_{es,0}+Ki_{G}+Ki_{IR})P_{e,1}⁻+Kₑ⁻P_{g,1}

P_{s,s}=−KₛₛPₛₛ+K_{ss,0}(P_{e,0}⁻+P_{e,1}⁻)+KₛP_{x,g}

P_{s,g}=−(K_{sg,0}+K_{sg,1})P_{x,g}−KₛP_{x,g}+KₛₛP_{x,e}

P_{g}⁰=Kₑ⁰P_{g}⁰+Kⱼ⁰Pₓ⁰+(Kᵢ_{_{G}}+Kᵢ_{_{IR}})(P_{e,0}⁻+P_{e,1}⁻)

Pₑ⁰=−(K_{f}⁰+Kr_{G}+Kr_{IR})Pₓ⁰+Kₑ⁰P_{g}⁰

In the above equations, P⁻_{g,0} and P⁻_{g,1} represent the population in the mₛ=0 and mₛ=±1 triplet ground states of the negatively charged NV, respectively, P⁻_{e,0} and P⁻_{e,1} represent the population in the mₛ=0 and mₛ=±1 triplet excited states of the negatively charged NV, respectively, P⁰_{g} and P⁰ₑ represent the populations of the neutral charge NV ground and excited states, respectively, and P_{s,g} and P_{s,e} represent the populations in the ground and excited singlet states of the negatively charged NV, respectively. K⁻ₑ and K⁰ₑ represent the green laser-induced excitation rates of NV⁻ and NV⁰ ground states to the excited states, respectively, K⁻ₛ represents the IR laser-induced excitation rate from the ground singlet state to the excited singlet state, K⁻_{f} and K⁰_{f} represent the fluorescence rate from the NV⁻ and NV⁰ excited states to their ground states, respectively, K⁻_{ss, rad} and K⁻_{ss, nonrad} represent the radiative and nonradiative decay rates from the excited singlet state to the ground singlet state, respectively, Fₚ represents the Purcell factor, which enhances the radiative rate, K⁻_{es,0} and K⁻_{es,1} represent the decay rates from the triplet excited states to the excited singlet state, respectively, K⁻_{sg,0} and K⁻_{sg,1} represent the decay rates from the ground singlet state to the NV⁻mₛ=0 and mₛ=±1 triplet ground states, respectively, K_{iG} and K_{iIR} represent the green and IR excitation-induced ionization rates, respectively, and K_{rG} and K_{rIR} represent the green and IR excitation-induced recombination rates, respectively.

The achievable red fluorescence spin-readout SNR, assuming 100% collection and perfect detection without external noise sources (such as dark counts) is illustrated in FIG. 3, where FIGS. 3A and 3B depict the absolute SNR, described in Eq. (1) for bulk and surface NVs, respectively, over a wide range of green excitation powers and readout durations. FIGS. 3C and 3D present the bulk (FIG. 3C) and surface (FIG. 3D) NV SNRs for the same power and duration regimes normalized by the square root of the pulse duration in μs. The significant difference in SNR between bulk and surface NVs stems from differences in the ionization cross section of the ³E₂ levels.

### Example 2: Description of IR Fluorescence-Based Spin Readout Scheme

The pulsed sequence, depicted in FIG. 4A, starts with a short and strong green laser pulse, exciting the NV from the ground state (3A₂) to the excited state (3E₂) and populating the singlet ground state (¹E₁) of almost only mₛ=±1 polarized NVs. Next, a short delay (represented by τ) is introduced to avoid undesired ionization from the excited triplet state, followed by a strong and long 980 nm pulse that excites the NV from the ground singlet state (¹E₁) to the singlet excited state (¹A₁) while collecting the emitted 1042-nm fluorescence. Due to the fact that the IR laser does not excite the triplet ground state, no mixing processes are expected, enabling a relatively long measurement. By carefully tuning the green laser pulse power and duration, the sequence can be repeated three times before significant mixing (via the singlet manifold or ionization/recombination processes) takes place, thus enhancing the signal.

Despite the poor radiative coupling between the ¹A₁ and ¹E₁ levels, the fast decay rate from the ¹A₁ state together with the relatively long shelving time in the ¹E₁ state, enable a large number of cycles before the NV decays back to the ³A₂ ground state without risking photo-ionization, allowing for a large enough number of photons to be collected during a single measurement, for high enough excitation powers.

FIG. 4 depicts the IR fluorescence spin-readout SNR as a function of IR laser power and pulse duration of bulk and surface NVs, with delay duration τ=10 ns (optimized with respect to the excited state lifetime). The laser power and pulse duration are scaled logarithmically to cover all of the relevant parameter space. Perfect collection and detection efficiencies are assumed for comparison with the results shown in FIG. 3. IR-induced ionization is neglected from the singlet state, for which the cross section is currently unknown (but assumed to be small), and consider a radiative to nonradiative coupling ratio of 1/1000. FIGS. 4B and 4C present the calculated absolute SNR for bulk and surface NVs, showing an expected significant enhancement of the spin-state readout SNR compared to the red fluorescence spin-readout scheme for high enough IR power. In addition, in this scheme the SNR grows monotonically with readout duration due to the absence of spin mixing. FIGS. 4D and 4E present the calculated normalized SNR for bulk and surface NVs for the IR fluorescence method, showing that the normalized SNR can reach higher values than that of the red fluorescence spin-readout SNR for bulk and surface NVs, for strong excitation powers.

### Example 3: Means for Improving IR Fluorescence Spin-Readout SNR

To further improve the spin-readout SNR shown in FIG. 4 while reducing the necessary IR excitation power, overcoming the weak fluorescence signal resulting from the nonradiative nature of the ¹A→¹E decay is needed. Thus, utilization of optical/plasmonic antennas, hyperbolic metamaterials or a photonic crystal cavity is proposed to strengthen the radiative coupling between the ¹A and ¹E states and thus increase the singlet fluorescence signal.

Photonic crystal structures with small mode volumes (V≈(λ/n)³) and high-quality factors (high frequency-to-bandwidth ratio in the resonator) are now within reach, and together with the relatively narrow IR fluorescence spectral width, are expected to provide high Purcell factors, especially for nano-diamonds and diamond films, but also potentially for bulk diamonds.

The Purcell factor, an enhancement of the spontaneous emission rate from the excited state due to radiative coupling, depends on the quality factor and mode volume in the following way:

$${F}_{P} = \frac{3}{4 {π}^{2}} {( \frac{λ}{n} )}^{3} \frac{Q}{V} , \qquad ( 3 )$$

where λ represents the wavelength, Q represents and quality factor, n represents the refractive index, and V represents the mode volume. In terms of the rate equations, the radiative part of the decay rate is multiplied by the Purcell factor. The fact that only approximately 0.1% of the decay results in photon emission holds great potential for enhancing the signal level and thus the SNR. In addition, the high emission directionality induced by a photonic crystal structure may dramatically increase the collection efficiency, and thus the number of photons detected.

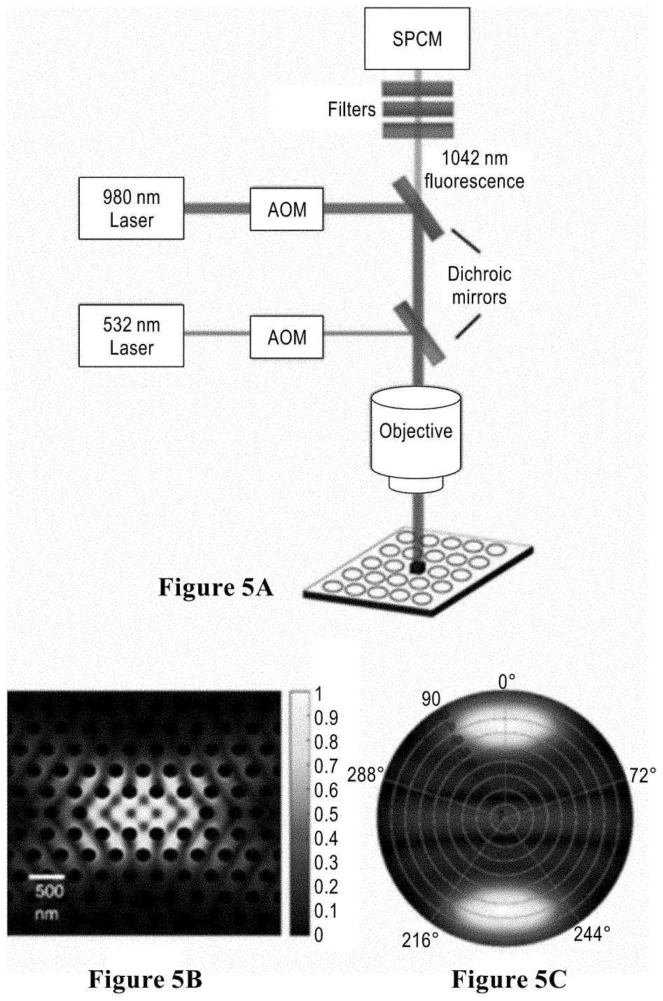

One of the suggested experimental systems is depicted in FIG. 5A. Green and detuned IR lasers excite the triplet (³A₂) and singlet (¹E₁) ground states, respectively, while Acousto-Optic Modulators (AOMs) modulate them. Two dichroic mirrors with proper cutoff wavelengths (533 nm-979 nm and 981 nm-1041 nm for the green and IR lasers, respectively) direct the lasers onto the objective and enable fluorescence collection on a single-photon counter module (SPCM), after the unwanted red fluorescence and reflected green and IR lasers are filtered out. The objective focuses the light onto the diamond sample, here illustrated as a nano-diamond, to reach the high intensity IR excitation needed for driving the singlet transition efficiently. FIGS. 5B and 5C illustrate the electric field near-field and far-field energy densities, as well as the photonic crystal cavity structure, optimized for nano-diamonds. The cavity structure is a 250-nm-thick silicone-nitride hexagonal PHC L3 cavity with five neighboring hole positions shifted. For this structure, the refractive index is 2, the lattice constant, a, is 450 nm and hole radius is 125 nm, and the positions of the holes were shifted by 0.315a, 0.35a, 0.118a, 0.205a, and 0.284a. The far-field energy density enables approximately 45% collection efficiency with numerical aperture of 0.95, while the near-field simulations predict a quality factor of about 2650 for this structure. Considering the small mode volume of this structure, 0.27 (λ/n)³, the resulting Purcell factor according to Eq. (3), which is manifested by K⁻s in FIG. 2, can reach up to 2343, and thus significantly enhance the emission and the number of photons collected. Simulation over a wide range of wavelengths was performed to verify the existence of a single resonant mode in the spectral range of 500 nm-1100 nm, ensuring no enhancement of the radiative decay of the main transition (³E to ³A). Similar calculations for diamond membranes and bulk diamonds predict quality factors of up to 13,300 and 790 with mode volumes of 0.38 (λ/n)³ and 0.8 (λ/n)³, respectively, resulting in Purcell factors of up to 8355 for diamond membranes and 235 for bulk diamonds.

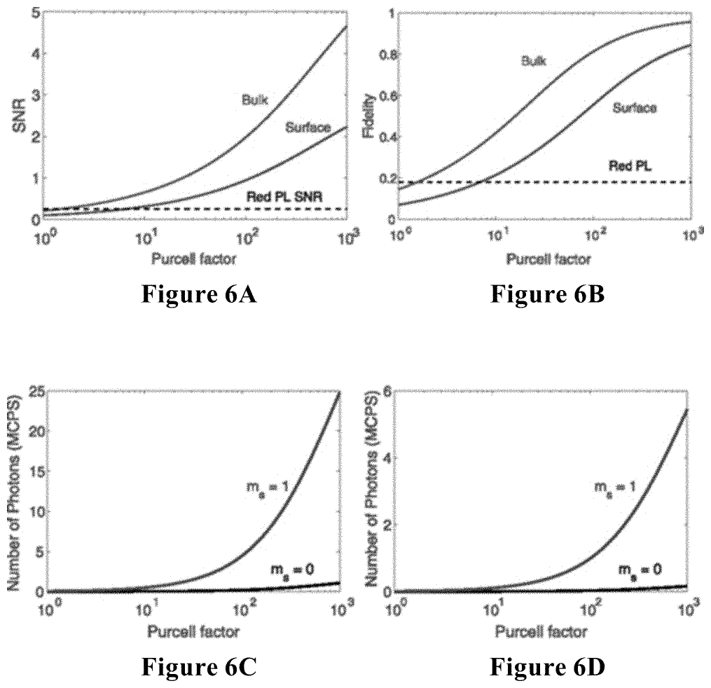

The expected spin-readout SNR and fidelity under 1W of IR excitation (inside the cavity) and a short readout duration (1 ns), as a function of Purcell factor for both surface (red line) and bulk (blue line) NVs are illustrated in FIG. 6. For this calculation, the Purcell factor was manifested by the radiative part of the rate K⁻ₛ in FIG. 2. Based on the figure, the scheme provides a fivefold enhancement of the spin-readout SNR for a feasible Purcell factor of 40, which was already achieved for silicon-vacancy centers, and more than an order of magnitude enhancement for Fₚ=300 and Fₚ=1000 (which are significantly lower than the Purcell factors calculated for nano-diamonds and diamond membranes) for bulk and surface NVs, respectively, thus exceeding the single-shot readout threshold. The SNR can reach even higher values for readout duration >1 μs and higher excitation powers. Thus, the magnetic field sensitivity, which obeys the following relation:

$$η ∝ δ B \sqrt{T} ∝ \frac{1}{SNR} , \qquad ( 4 )$$

could be reduced by more than an order of magnitude as well (where T is the measurement time and δB is the minimum magnetic field that can be measured during this time).

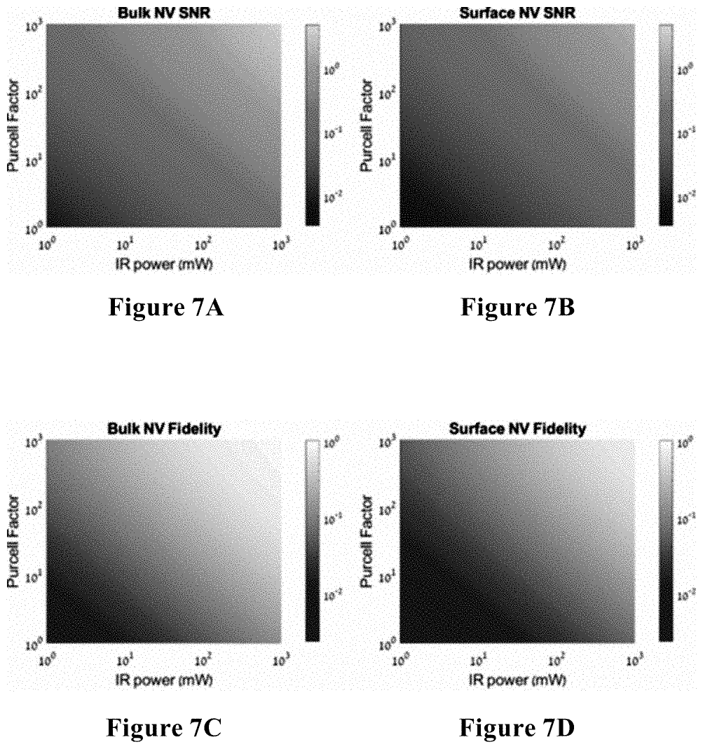

Presented in FIGS. 6B and 6C is a calculation of the number of photons emitted from the mₛ=0 and mₛ=±1 spin states as a function of the Purcell factor for the same excitation power during the 1 μs readout duration, showing that a higher number of photons is expected to be emitted during the readout sequence, while the contrast between the two spin states is sustained. FIG. 7 depicts the interplay between the IR excitation power and the Purcell factor in terms of their impact on the spin-readout SNR and fidelity. This is calculated both for bulk and surface NVs, over a wide range of parameters. Although the excitation power and Purcell factor change different parameters in the rate equations, low laser power can be compensated for by a higher Purcell factor and vice versa. Thus, a measurement with 100 mW of laser excitation still produces a sixfold enhancement in the readout SNR for Fₚ≈1000, according to the simulation.

1. A process for enhancing sensitivity in measuring spin state in nitrogen vacancy (NV) centers in a diamond sample, the process comprising applying an optical excitation radiation to a diamond having at least one nitrogen vacancy (NV) center, the radiation comprising light having a wavelength between 400 and 638 nm, illuminating the sample with light having a wavelength between 700 and 1042 nm, and detecting, measuring and/or counting photons emitted from the at least one NV center.

2. A process for enhancing sensitivity in measuring spin state in nitrogen vacancy (NV) centers in a diamond sample, the process comprising:
irradiating a diamond having at least one nitrogen vacancy (NV) center with a light having a wavelength between 400 and 638 nm, to thereby excite the NV centers,
irradiating the diamond with a light having a wavelength between 700 and 1042 nm, and
detecting photons emitted from the at least one NV centers, at wavelengths ranging between 700 and 1050 nm.

3. The process according to claim 1, wherein the step of detecting photons emitted from the at least one NV centers is at wavelengths between 1040 and 1050 nm.

4. The process according to claim 2, further comprising a step of enhancing the fluorescence emission signal.

5. The process according to claim 4, wherein said enhancing fluorescence emission comprises coupling a singlet transition emission to a photonic structure.

6. The process according to claim 5, wherein the photonic structure is an optical antenna, a plasmonic antenna, a hyperbolic metamaterial (HMM) or a photonic crystal cavity.

7. The process according to claim 1, wherein the optical excitation with light in a wavelength between 400 and 638 nm is for a duration between 1 and 3 us.

8. The process according to claim 1, wherein the illuminating with light in a wavelength between 700 and 1042 nm is for a duration between 1 ns and 5 ms or between 1 ns and 1 ms.

9. A device comprising a diamond sample comprising at least one nitrogen vacancy (NV) center, a first illumination source configured and operable to illuminate the diamond sample at a wavelength in a spectral range between 400 and 638 nm, a photon counter, and a second illumination source configured and operable to illuminate the diamond sample at a wavelength in a spectral range between 700 and 1042 nm.

10. A magnetometer device comprising a diamond having at least one nitrogen vacancy (NV) center comprising one or more electronic spins, wherein the electronic spins are configured to align with the diamond crystallographic axis in response to optical excitation radiation applied to the at least one NV center; and a photon counter configured to detect output optical radiation at the IR range correlated with the electronic spins when subjected to an optical enhancement.

11. The device according to claim 9, wherein the photons counter is a device comprising a single-photon detector (SPD).

12. The device according to claim 11, wherein the photon counter is selected from a photodiode, a single photon detector, a superconducting nanowire, a photomultiplier, a Geiger counter, a single-photon valance diode, a transition edge sensor, a scintillation counters and a charge-coupled device.

13. The device according to claim 12, wherein the photons counter is a device comprising a single-photon detector (SPD).

14. The device according to claim 12, wherein the photon counter is selected from a photodiode, a single photon detector, a superconducting nanowire, a photomultiplier, a Geiger counter, a single-photon valance diode, a transition edge sensor, a scintillation counters and a charge-coupled device.

15. The device according to claim 9, further comprising a microwave radiation element, a polarization control element, a light modulation device, a lock-in amplifier, a time tagging element, a data acquisition, a processing device, a sequence generation device, a magnetic field generation element, or an optical element.

16. The device according to claim 10, further comprising a microwave radiation element, a polarization control element, a light modulation device, a lock-in amplifier, a time tagging element, a data acquisition, a processing device, a sequence generation device, a magnetic field generation element, or an optical element.

17. The device according to claim 9, being a magnetometer.

18. The device according to claim 9, being a quantum communication device or a spintronic device.
